(19) United States
(12) Patent Application Publication
(10) Pub. No.: US 2008/0204158 A1
(43) Pub. Date: Aug. 28, 2008

(54) APPARATUS AND METHOD FOR GENERATING A SUPPLY VOLTAGE-DEPENDENT CLOCK SIGNAL

(75) Inventor: Uwe Weder, Au (DE)

Correspondence Address: DICKSTEIN SHAPIRO LLP, 1177 AVENUE OF THE AMERICAS 6TH AVENUE, NEW YORK, NY, 10036-2714, US

(73) Assignee: INFINEON TECHNOLOGIES AG, Munich (DE)

(21) Appl. No.: 11/685,656

(22) Filed: Mar. 13, 2007

(30) Foreign Application Priority Data
Feb. 27, 2007 (DE) 10 2007 009 525.4

(51) Int. Cl. H03B 5/04

(52) U.S. Cl. 331/177 V

(57) ABSTRACT

An integrated circuit having a logic circuit having logic elements in a signal path having a signal propagation duration, wherein the logic elements have switching times depending on a supply voltage, and having an input for a clock signal, and an oscillator circuit having oscillator elements having switching times depending on the supply voltage, so that a frequency of the clock signal is adapted depending on the supply voltage to allow signal propagation of a signal through the signal path during a clock cycle of the clock signal in a case of a supply voltage drop, and having an output for the clock signal connected to the input of the logic circuit.

### CROSS-REFERENCE TO RELATED APPLICATION

This application claims priority from German Patent Application No. 10 2007 009 525.4, which was filed on Feb. 27, 2007, and is incorporated herein by reference in its entirety.

### TECHNICAL FIELD

The present invention relates to a concept for generating a clock signal depending on a supply voltage for an integrated logic circuit, as it may be used in particular for integrated circuits having an unstabilized voltage supply.

### BACKGROUND

In general, a synchronizing clock signal is required for integrated digital logic circuits. It is often provided by an external or internal oscillator circuit. In most cases, a defined clock frequency f_{clk} with a minimum of variations depending on temperature and supply voltage is required by product requirements. Normally, so-called crystal oscillators are used for the external generation of clocks. Ideally, they have no and/or only little variations depending on temperature and supply voltage. In the case of an on-chip clock generation, an attempt is made to approximate this ideal state by using so-called bandgap reference voltages and/or constant currents derived therefrom.

In order to supply integrated circuits that, for example, internally require various supply voltages with only one external supply voltage, normally an internal voltage regulator and/or on-chip voltage regulator is provided, which is normally implemented as continuously operating linear regulator. If, at the output of such an on-chip voltage regulator, there is no or no correspondingly large buffer capacity, for example for reasons of dimensioning, there will generally be short voltage drops or voltage peaks, for example in the case of load changes at the output of the voltage regulator, due to a finite regulating time. This means that the internal voltage regulator provides an unstabilized supply voltage for an integrated circuit.

Digital circuits and/or logic elements or gates included in digital circuits in most cases have supply voltage-dependent, temperature-dependent and process-dependent switching speeds and/or switching times t_{switch}. For example, logic elements tend to switch faster in the case of higher supply voltages and to switch more slowly in the case of lower supply voltages.

In an integrated logic circuit, there is generally a signal path having the longest signal propagation duration within the logic circuit. This signal path is generally referred to as critical path. For proper operation of an integrated logic circuit, there should always be the guarantee that a cycle of the clock signal is long enough to allow complete signal propagation over the critical path. However, if a logic signal takes a longer time period than a cycle of the clock signal to propagate through the critical path, there may be incorrect signal states at the end of a clock cycle. This may lead to logic false statements and even to complete failure of the integrated logic circuit. If, for example, an oscillator circuit provides a clock signal with fixed frequency f_{clk}=33 MHz, and if the signal propagation duration over the critical path is increased by a supply voltage drop, for example from 26 ns (nanoseconds) to 32 ns, and if the oscillator period duration remains fixed at 30 ns, the result may be a system crash.

In order to avoid this, the clock signal generation may be designed, for example, for a so-called “worst case scenario”. This means that, for example, a lowest supply voltage to be expected is assumed and therefore an oscillator circuit is sized so that the generated clock signal comprises a clock cycle that, in any case, takes longer than the signal propagation duration to be expected through the critical path for the lowest supply voltage to be expected. Fixed oscillator frequencies, independent of the supply voltage, may, for example, be generated on-chip by ring oscillators with analog parts (current sources) for adjustment. Furthermore, ring oscillators with locally concentrated capacitances are possible. Furthermore, fixed oscillator frequencies according to the worst case scenario may be implemented with analog oscillator circuits with saw tooth generation for period duration determination.

Since the “worst case scenario” described above mostly occurs only in relatively rare cases, the integrated logic circuit and/or the clock generation for the integrated logic circuit is implemented inefficiently for the case of normal supply voltage conditions.

Therefore, a supply voltage-dependent clock generation would be desirable to allow optimum performance of the integrated logic circuit in normal operation, i.e. with supply nominal voltage, and to adapt the clock signal to the longer signal propagation durations in the case of supply voltage drops to prevent logic errors and/or system crashes.

### SUMMARY

According to an embodiment, an integrated circuit may have: a logic circuit having logic elements in a signal path having a signal propagation duration, wherein the logic elements have switching times depending on a supply voltage, and having an input for a clock signal; and an oscillator circuit having oscillator elements having switching times depending on the supply voltage, so that a frequency of the clock signal is adapted depending on the supply voltage to allow signal propagation of a signal through the signal path during a clock cycle of the clock signal in a case of a supply voltage drop, and having an output for the clock signal connected to the input of the logic circuit.

According to another embodiment, an integrated circuit may have: a logic circuit having logic elements in a critical signal path, which is a path in the logic circuit that has the longest signal propagation duration, wherein the logic elements have switching times depending on a supply voltage, and having an input for a clock signal; and an oscillator circuit having a ring oscillator structure with inverters connected in series, which have switching times depending on the supply voltage, so that a frequency of the clock signal is decreased in a case of a decreasing supply voltage and is increased in a case of an increasing supply voltage to allow signal propagation of a signal through the critical signal path during a clock cycle of the clock signal in a case of a supply voltage drop, and having an output for the clock signal connected to the input of the logic circuit.

According to another embodiment, a device on a chip with an unstabilized voltage supply, wherein the chip has an integrated logic circuit having logic elements in a signal path that has a signal propagation duration, wherein the logic elements have switching times depending on a supply voltage, may have: a unit for generating a clock signal for the integrated logic circuit depending on the supply voltage, so that a frequency of the clock signal is adapted depending on the supply voltage to allow signal propagation of a signal through the signal path during a clock cycle of the clock signal in a case of a supply voltage drop.

According to another embodiment, a method for clock generation on a chip with an unstabilized voltage supply, wherein the chip has an integrated logic circuit having logic elements in a signal path having a signal propagation duration, wherein the logic elements have switching times depending on a supply voltage, may have the steps of: generating a clock signal for the integrated logic circuit depending on the supply voltage, so that a frequency of the clock signal is adapted depending on the supply voltage to allow signal propagation of a signal through the signal path during a clock cycle in a case of a supply voltage drop.

According to another embodiment, a method for producing an integrated circuit may have the steps of: generating a logic circuit in a chip having logic elements in a signal path having a signal propagation duration, wherein the logic elements have switching times depending on a supply voltage; and providing an oscillator circuit in the chip having oscillator elements having switching times depending on the supply voltage, so that a frequency of a clock signal of the oscillator circuit depends on the supply voltage to allow signal propagation of a signal through the signal path during a clock cycle of the clock signal in a case of a supply voltage drop.

According to embodiments, the present invention provides an integrated circuit having a logic circuit with logic elements in a signal path having a signal propagation duration, wherein the logic elements have switching times depending on a supply voltage, and with an input for a clock signal, and an oscillator circuit having oscillator elements having switching times depending on the supply voltage, so that a frequency of the clock signal is adapted depending on the supply voltage to allow signal propagation of a signal through the signal path during a clock cycle of the clock signal in the case of a supply voltage drop, and with an output for the clock signal connected to the input of the logic circuit.

### BRIEF DESCRIPTION OF THE DRAWINGS

Preferred embodiments of the present invention will be explained in more detail below with reference to the accompanying drawings, in which:

FIG. 1 shows a schematic flow diagram of a method for generating a clock signal according to an embodiment of the present invention;

FIG. 2 shows a schematic illustration of a switching time of digital logic elements depending on a supply voltage of the logic elements;

FIG. 3 shows a schematic block circuit diagram of an integrated circuit having a logic circuit, an oscillator circuit and an unstabilized voltage supply according to an embodiment of the present invention;

FIG. 4 shows a schematic block circuit diagram of an oscillator circuit according to an embodiment of the present invention;

FIG. 5 shows a block circuit diagram of an oscillator circuit according to a further embodiment of the present invention;

FIG. 6 shows a circuit diagram of a first oscillator element having an inverter according to an embodiment of the present invention;

FIG. 7 shows a circuit diagram of a second oscillator element having an inverter and additionally connectable transistors according to an embodiment of the present invention;

FIG. 8 shows a circuit diagram of a third oscillator element having an inverter and additionally connectable capacitances according to an embodiment of the present invention; and

FIG. 9 shows a circuit diagram of a third oscillator element having an inverter, additionally connectable transistors and additionally connectable capacitances according to embodiment of the present invention.

### DETAILED DESCRIPTION

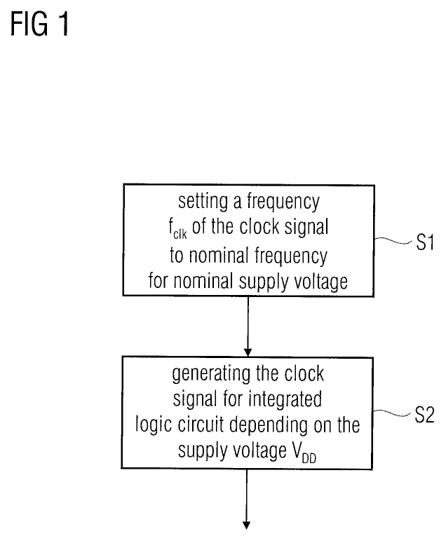

FIG. 1 shows a flow diagram for explaining a method for clock generation on a chip having an unstabilized voltage supply, wherein the chip comprises an integrated logic circuit having logic elements in a signal path having a signal propagation duration, wherein the logic elements comprise switching times depending on a supply voltage, according to an embodiment of the present invention.

In a first step S1, a clock frequency f_{clk} of the clock signal is set to a nominal frequency f_{clk,nom} with a nominal supply voltage V_{DD,nom}. In a second step S2, the clock signal for the integrated logic circuit is generated depending on the supply voltage V_{DD}, so that the frequency f_{clk} of the clock signal is adapted depending on the supply voltage V_{DD} to allow signal propagation of a signal through the signal path during a clock cycle in the case of a supply voltage drop.

The first step S1 describes dimensioning and/or calibration of an oscillator circuit integrated on a chip together with the integrated logic circuit, so that the nominal frequency f_{clk,nom} is set by connecting a certain number of oscillator elements. According to embodiments, the oscillator elements include digital inverters connected in series, as will be explained in more detail below. According to embodiments, a more precise setting and/or adjustment of the nominal frequency f_{clk,nom} is achieved by connecting one or more capacitances between an output of one or more oscillator elements of the oscillator generating the clock signal to reduce the switching time of the one or more oscillator elements and thus reduce the frequency f_{clk} of the clock signal. Furthermore, a still more precise adjustment of the nominal frequency f_{clk,nom} is achieved, according to embodiments, by connecting one or more transistors in parallel to one or more transistors of an inverter of one or more oscillator elements of the oscillator to increase the switching time of the one or more oscillator elements and thus to correspondingly increase the frequency f_{clk} of the clock signal.

Since the oscillator elements, as mentioned above, have digital inverters which, just like the logic elements of the integrated logic circuit, have switching times t_{switch} depending on the supply voltage V_{DD}, the clock signal for the integrated logic circuit is adapted depending on the supply voltage V_{DD}, so that the clock frequency is reduced in the case of a supply voltage drop to allow the signal propagation of a signal through the critical path during a clock cycle in the case of a supply voltage drop.

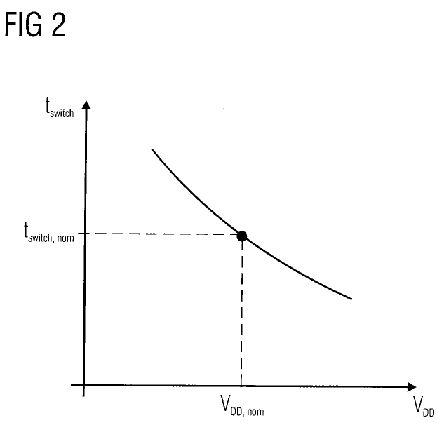

A fundamental relationship between supply voltage and switching time of digital logic elements or digital inverters is shown in FIG. 2.

Digital logic elements or logic gates generally have a supply voltage-dependent switching speed and/or switching time t_{switch} (V_{DD}). Logic elements tend to switch faster in the case of higher supply voltages V_{DD}, i.e. t_{switch} becomes smaller, and to switch more slowly in the case of lower supply voltages, i.e. t_{switch} becomes larger.

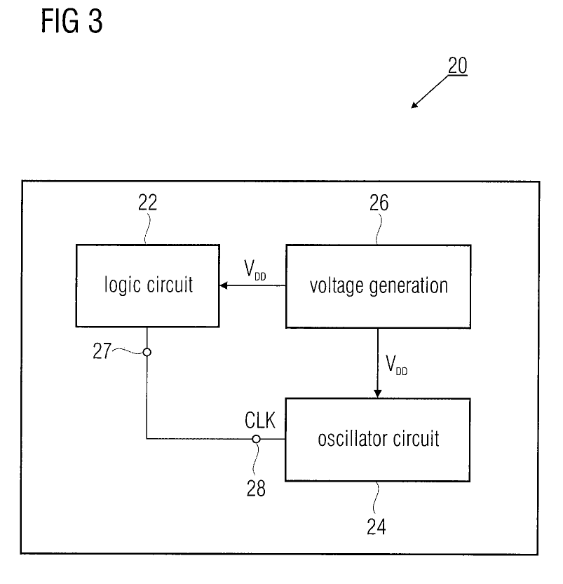

The structure of an integrated circuit with a logic circuit and an oscillator circuit and particularly the structure of an integrated oscillator circuit will be explained in more detail below based on FIGS. 3 to 8.

FIG. 3 shows an integrated circuit 20 having a logic circuit 22, an oscillator circuit 24, a so-called on-chip oscillator and a voltage generator 26 for generating an unstabilized supply voltage V_{DD}, a so-called on-chip voltage regulator. Both the logic circuit 22 and the oscillator circuit 24 are supplied by the unstabilized supply voltage V_{DD}. The logic circuit 22 comprises an input 27 for a clock signal, which is provided at an output 28 of the oscillator circuit. The input 27 of the logic circuit and the output 28 of the oscillator circuit are connected to each other.

The logic circuit 22 has logic elements, such as AND, NAND, OR, NOR, XOR gates, in a signal path having a signal propagation duration, wherein the logic elements have switching times t_{switch} depending on the supply voltage V_{DD}, as it is shown in principle in FIG. 2. According to embodiments, the signal path is a critical signal path having a longest signal propagation duration of the logic circuit 22.

The oscillator circuit 24 comprises oscillator elements having switching times depending on the supply voltage V_{DD} (cf. FIG. 2), so that the frequency f_{clk} of the clock signal is adapted depending on the supply voltage V_{DD} to allow signal propagation of a signal through the signal path, particularly the critical path, during a clock cycle of the clock signal in the case of a supply voltage drop. According to embodiments, the oscillator elements of the oscillator circuit 24 are adapted to provide an extension of the clock cycle of the clock signal in the case of a supply voltage drop, which differs less than 20%, preferably less than 10% and more preferably less than 5% from an extension of the signal propagation through the signal path in the logic circuit 22 caused by the supply voltage drop. Furthermore, the oscillator elements of the oscillator circuit 22 are adapted to reduce the frequency f_{clk} of the clock signal in the case of a decreasing supply voltage V_{DD} and to increase it in the case of an increasing supply voltage V_{DD}.

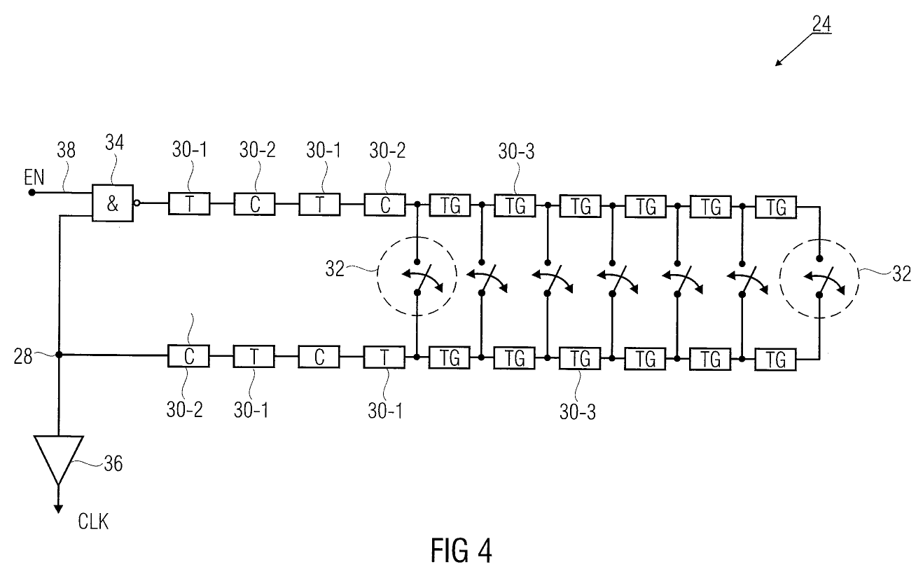

Embodiments of the integrated oscillator circuit 24 and particularly the oscillator elements are explained in more detail below with reference to FIGS. 4-6.

FIG. 4 shows a schematic block circuit diagram of the integrated oscillator circuit 24 according to an embodiment of the present invention.

The oscillator circuit 24 comprises oscillator elements 30-1, 30-2 and 30-3 connected in series to form a ring structure. The oscillator elements 30 all include digital inverters. With the help of the switches 32, a certain number of oscillator elements 30 may be connected one after the other. For oscillating an oscillator signal at an output 28 of the oscillator circuit, an inverter chain with an odd number of inverters is necessary. On the input side, the inverter chain and/or the chain of oscillator elements 30 is connected to a NAND gate 34 whose first input is coupled to the output 28 and/or the clock signal. A second input of the NAND gate 34 is a clock activation signal 38. The output 28 is connected to a buffer 36 to couple out the clock signal.

With the help of the clock activation signal 38, the clock signal generation may be activated and/or deactivated depending on the level (“1”, “0”).

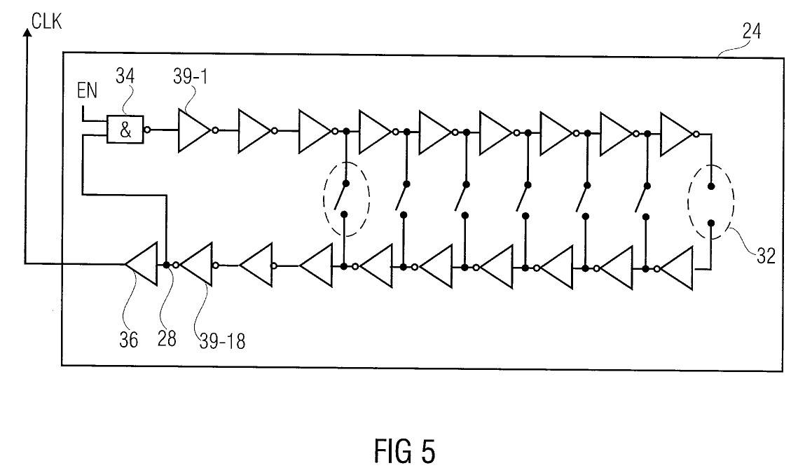

According to an embodiment of the present invention, the oscillator elements 30-1, 30-2 and 30-3 respectively comprise digital inverters 39, as it is schematically illustrated in FIG. 5.

The inverters 39 are connected in series to form a ring oscillator structure. At its output, an inverter 39 indicates the signal present at its input, but with an inverted level. The same applies to an odd number (2n+1) (n integer) of inverters connected in series. If the signal at the output 28 is coupled back to the input of the first inverter 39-1 with the help of the NAND gate 34 and the activation signal 38, the integrated oscillator circuit 24 oscillates due to the finite switching speed t_{switch} of the inverter devices 39 and/or the inverter chain. In the schematic block diagram shown in FIG. 5, 19 inverters form the oscillator in the shown switch position including the NAND gate. The buffer 36 serves as a driver for coupling out the clock signal.

With (2n+1) equal inverters, the clock frequency f_{clk} is proportional to 1/[t_{switch}*(2n+1)], i.e. f_{clk}˜1/[t_{switch}*(2n+1)]. t_{switch} means the finite switching time of an inverter device 39. This switching time t_{switch} depends on the supply voltage V_{DD}.

Referring to FIG. 4, two oscillator elements 30-3 may respectively be switched into the oscillator element chain and/or off by the switch positions of the switches 32. It is to be noted that always only one of the shown switches 32 is closed, while the other switches remain open. While a relatively rough adjustment of the clock frequency may be done at the output 28 by switching the oscillator elements 30-3 on and off, the oscillator elements 30-1, 30-2 respectively serve for fine and/or medium adjustment of the clock frequency f_{clk}.

An inverter in CMOS technology typically comprises both NMOS and PMOS transistors. In order to reduce the switching time of an inverter, according to embodiments, additional transistors are connected in parallel to the NMOS and/or PMOS transistors of an inverter to increase the switching speed of the inverter and/or to reduce the switching time. In that way, a fine clock frequency adjustment may be performed. This means that reference numeral 30-1 designates oscillator elements having parallel transistors that may be connected to an inverter to be able to perform clock frequency fine adjustment.

Reference numeral 30-2 designates oscillator elements comprising one or more capacitances selectively connectable between the output of an inverter and a reference potential to thus slow down the switching speed of the oscillator element 30-2 and thus the clock frequency of the clock signal. By means of the capacitances selectively connectable between the output of the oscillator element 30-2 and the reference potential, frequency tuning of medium accuracy may be performed.

According to embodiments, the oscillator element indicated by reference numeral 30-3 only comprises a CMOS inverter without additionally connectable transistors and additionally connectable capacitances.

By means of certain switch positions of the switches 32 and further switch positions (not shown) within the oscillator elements 30-1 and/or 30-2, the oscillator circuit 24 shown in FIG. 4 may be set to a nominal clock frequency f_{clk,nom} for a nominal supply voltage V_{DD,nom}. This nominal clock frequency f_{clk,nom} is set so that all signal propagation times within the logic circuit 22 are within a clock cycle for the nominal supply voltage V_{DD,nom}.

Since the signal runtime through the oscillator elements of the oscillator circuit 24 shown in FIG. 4 for the nominal supply voltage V_{DD,nom} is larger than the signal runtime through the critical path of the logic circuit for the nominal supply voltage V_{DD,nom}, the signal runtime through the chain of oscillator elements in the case of supply voltage drops is still larger than the corresponding signal runtime through the critical path of the logic circuit 22. This is due to the fact that both the logic circuit 22 and the oscillator circuit 24 are supplied by the same unstabilized supply voltage V_{DD}. In the case of voltage drops, the signal runtime through the chain of oscillator elements and/or through the inverter chain of the oscillator circuit 24 is increased similarly to the signal runtime through the critical path of the logic circuit 22.

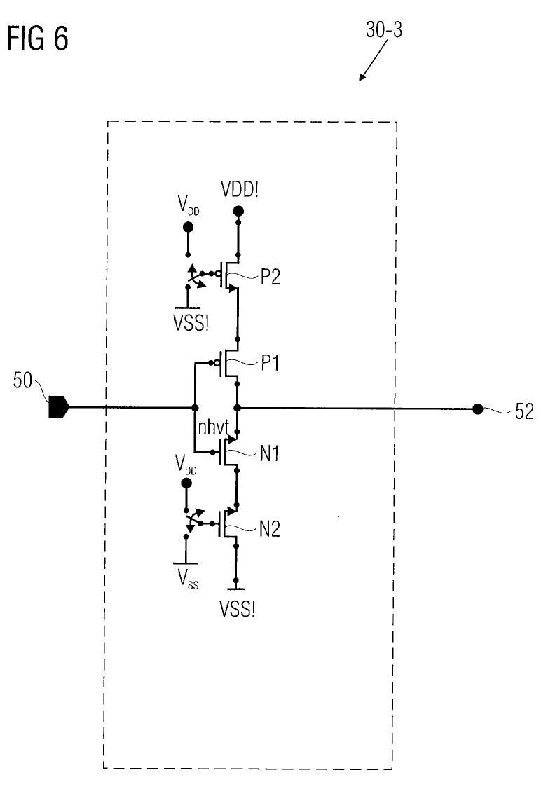

FIG. 6 shows a possible implementation of an oscillator element 30-3 for coarse adjustment of the clock frequency according to an embodiment of the present invention.

The oscillator element 30-3 comprises an inverter in CMOS technology having an NMOS transistor N1 and a PMOS transistor P1. The gate terminals of the NMOS transistor and the PMOS transistor N1 and P1 are connected to each other and form an input 50 of the oscillator element 30-3. The drain terminal of the NMOS transistor N1 is connected to the drain terminal of the PMOS transistor P1, wherein the drain terminal of the NMOS transistor N1 and the drain terminal of the PMOS transistor P1 are respectively connected to an output 52 of the oscillator element 30-3. Furthermore, the source terminal of the NMOS transistor N1 is connected to the drain terminal of an NMOS transistor N2. The gate terminal of the NMOS transistor N2 is coupled to the unstabilized supply potential V_{DD}. The source terminal of the NMOS transistor N2 is coupled to a reference potential VSS, wherein the reference potential VSS may, for example, be ground potential. The source terminal of the PMOS transistor P1 is connected to the drain terminal of a PMOS transistor P2. The gate terminal of the PMOS transistor P2 is at the reference potential VSS. The source terminal of the PMOS transistor P2 is at the unstabilized supply potential V_{DD}.

If the oscillator element 30-3 shown in FIG. 6 is not used for clock generation by a switch 32 correspondingly opened in the oscillator circuit 24, the gate terminal of the NMOS transistor N2 is connected to the reference potential VSS, and the gate terminal of the PMOS transistor P2 is connected to the unstabilized supply potential V_{DD}, as indicated in FIG. 6. Thus, an oscillator element 30-3 not needed is no longer driven, i.e. the inverter formed by the transistors N1 and P1 is put out of operation.

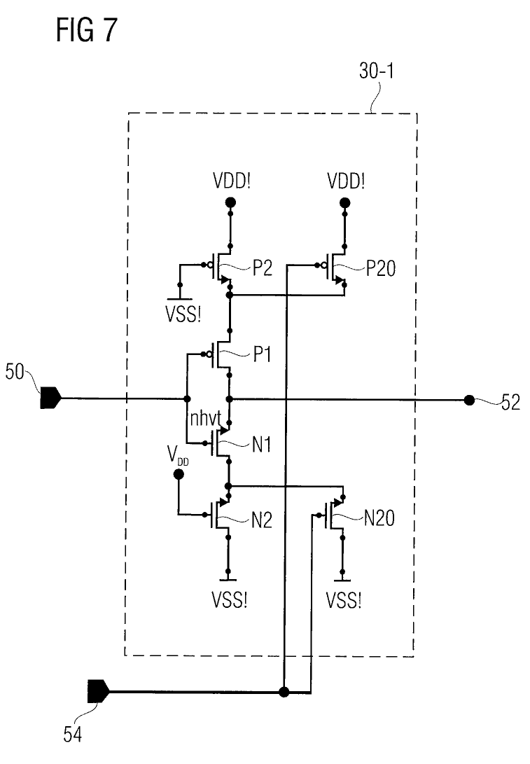

FIG. 7 shows a possible implementation of an oscillator element 30-1 for fine adjustment of the clock frequency according to an embodiment of the present invention.

The oscillator element 30-1 comprises an inverter in CMOS technology having an NMOS transistor N1 and a PMOS transistor P1 and transistors N2 and P2. The transistors N1, P1, N2 and P2 are connected to each other, as described with respect to FIG. 6. Furthermore, the source terminal of the NMOS transistor N1 and/or the drain terminal of the NMOS transistor N2 is connected to the drain terminal of an NMOS transistor N20. The gate terminal of the NMOS transistor N20 is coupled to a switch signal bus 54. The source terminal of the NMOS transistor N20 is coupled to a reference potential VSS, wherein the reference potential VSS may, for example, be ground potential. The source terminal of the PMOS transistor P1 and/or the drain terminal of the PMOS transistor P2 is connected to the drain terminal of a PMOS transistor P20. The gate terminal of the PMOS transistor P20 is coupled to the switch signal bus 54. The drain terminal of the PMOS transistor P20 is at the unstabilized supply potential V_{DD}.

According to embodiments, the two parallel transistors P20 and N20 may be individually connected via switch signals of the switch signal bus 54 to increase a switching speed of the inverter including the transistors N1, N2, P1 and P2.

Depending on whether a switch signal of the switch signal bus 54 simulates a logical “1” or a logical “0”, the transistors N20 and P20 are connected in parallel to the transistors N2 and/or P2 to increase a switching speed of the oscillator element 30-1.

According to embodiments, the transistors of the oscillator elements 30-1, 30-2 and 30-3 have channel lengths larger than channel lengths of transistors of the integrated logic circuit 22. The use of larger channel lengths has the advantage that current may be saved in the oscillator circuit. In this case, individual transistors exhibit a slightly different switching behavior as compared to the transistors in the logic circuit, depending on the supply voltage V_{DD}. Thus, an optimization with respect to equal oscillator/logic behavior or minimum current consumption may be made.

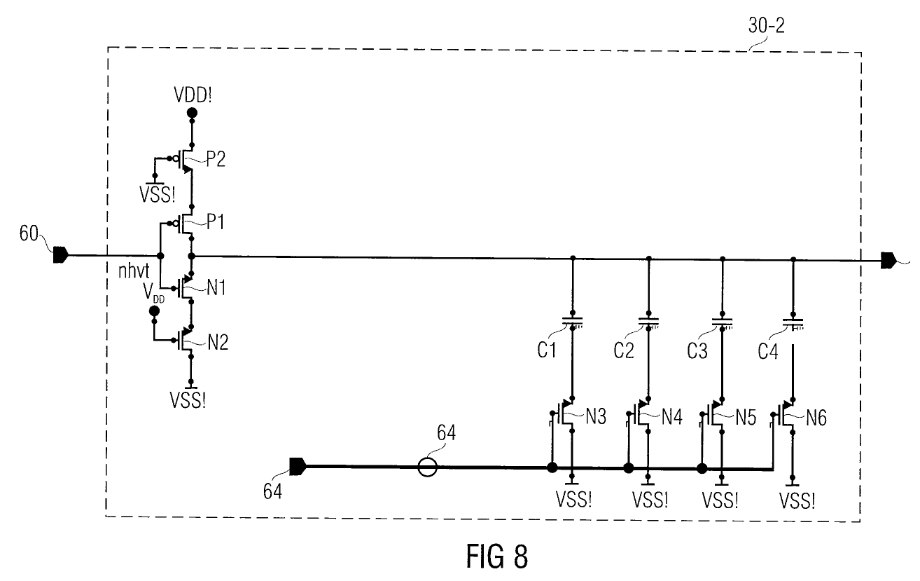

FIG. 8 shows an exemplary implementation of an oscillator element 30-2 for adjusting the clock frequency f_{clk} with medium accuracy.

The oscillator element 30-2 comprises an inverter including the MOS transistors N1, N2, P1 and P2, wherein the transistors are connected, as described with respect to FIG. 6. The gate terminals of the transistors N1 and P1 are connected to an input 60, wherein the connected drain terminals of the NMOS transistor N1 and the PMOS transistor P1 are connected to an output 62 of the oscillator element 30-2.

According to embodiments, one or more capacitances may selectively be connected between the output 62 and the reference potential VSS to thus slow down a switching speed of the oscillator element 30-2 and thus the clock frequency f_{clk} of the clock signal. In the example shown in FIG. 8, four capacitances C1, C2, C3, C4 are connectable between the output 62 and the reference potential VSS. More or less connectable capacitances are conceivable, of course. NMOS transistors N3, N4, N5 and N6 connected between the reference potential VSS and the capacitances act as switches. The NMOS transistors N3-N6 may selectively be connected through via logic signals of a signal bus 64 to connect the corresponding capacitances between the output 62 and the reference potential VSS. According to embodiments, the capacitance values of the capacitances C1-C4 are each in a range from 5 femtofarad to 15 femtofarad, so that a total capacitance resulting from the parallel connection of the capacitances is in a range from about 20 femtofarad to 60 femtofarad. The more capacitances are connected between the output 62 and the reference potential VSS, the slower is the switching behavior of the oscillator element 30-2. The switching of the capacitances thus allows medium adjustment of the clock frequency f_{clk}. According to embodiments, the capacitances C1, C2, C3, C4 each have different capacitance values to allow an at least approximately equal frequency step size for the tuning of the clock frequency f_{clk}.

The following will explain, by way of example, setting a nominal clock frequency f_{clk,nom} for a nominal supply voltage V_{DD,nom}.

If, for example, a nominal clock frequency f_{clk,nom} of 33 MHz is required, it may roughly be set by the selection of the switch positions of the switches 32, with reference to FIG. 4. In a next step, there is a medium-precise adjustment of the clock frequency f_{clk,nom} by connecting the capacitances of the oscillator elements 30-2. According to embodiments, the capacitances in the individual oscillator elements 30-2 are activated in a distributed way. This means that, before the capacitance C2 is, for example, activated in oscillator element 30-2, capacitance C1 is respectively activated first in all other oscillator elements 30-2.

After the medium-precise adjustment by the connection of the capacitances, the clock frequency f_{clk,nom} is, for example, below 33 MHz. In order to generate the 33 MHz in a sufficiently precise way, the parallel transistors N20 and/or P20 of the oscillator elements 30-1 are activated in a further step. The transistors P20 and N20 may be activated and/or deactivated individually in each oscillator element 30-1 to allow precise clock frequency setting. According to embodiments, the transistors P20 and N20 in the individual oscillator elements 30-1 are activated in a distributed way. This means that, before the transistor N20 is, for example, activated in the oscillator element 30-1, the transistor P20 is respectively activated first in all other oscillator elements 30-1. The same applies vice versa, of course.

If the nominal clock frequency f_{clk,nom} for the nominal supply voltage V_{DD,nom} has been set in the manner described above, the oscillator circuit 24 reduces and/or increases its output clock frequency f_{clk} at the output 28 automatically depending on the applied supply voltage V_{DD}. This means that a further adjustment or regulation is not necessary. Any change of the supply voltage V_{DD} directly changes the frequency f_{clk} finely with respect to clock. Any voltage drop increasing the length and/or signal propagation duration of the critical path in a certain clock also reduces the frequency f_{clk} and/or increases the period duration T_{clk} exactly for that clock, whereby the integrated logic circuit 22 may continue to operate stably.

If, for example, the signal propagation duration on the critical path changes from 26 ns to 32 ns, with a clock frequency f_{clk} of 33 MHz, due to a voltage drop, the integrated oscillator circuit 24 may be sized by corresponding dimensioning of the oscillator elements 30-1, 30-2 and 30-3 such that the oscillator period duration T_{clk} is extended from 30 ns to 36 ns. This makes the integrated circuit resistant to voltage drops.

According to a further aspect, the present invention provides a method for producing the integrated circuit 20 having a step of generating the logic circuit 22 in a chip comprising logic elements in a signal path having a signal propagation duration, wherein the logic elements have switching times t_{switch} depending on a supply voltage V_{DD}, and a step of providing the oscillator circuit 24 in the chip comprising oscillator elements 30 having switching times t_{switch} depending on the supply voltage V_{DD}, so that a frequency f_{clk} of a clock signal of the oscillator circuit depends on the supply voltage to allow signal propagation of a signal through the signal path during a clock cycle of the clock signal in the case of a supply voltage drop.

By using an inventive digital ring oscillator structure for an on-chip clock generation for an unstabilized voltage supply, as it can be found, for example, in chip cards, a change of the supply voltage is directly translated into a change of the generated clock frequency. By selecting a number of oscillator elements connected in series by means of the switches 32, a coarse adjustment of the generated clock frequency may be performed, for example in a 3 MHz raster. By an equal distribution of small capacitances in the oscillator elements 30-2, a setting of the clock frequency f_{clk} of medium accuracy (for example 0.3 MHz) may be performed. The capacitance values correspond approximately to input capacitances of gates of the logic circuit 22. A fine adjustment of the generated clock frequency f_{clk}, for example with an accuracy of 0.05 MHz, may be achieved by equal distribution of driver transistors in the oscillator elements 30-1.

The inventive concept allows to realize a supply voltage-dependent oscillator of high accuracy. The automatic adaptation of the clock frequency and/or the period duration of the clock signal to the signal propagation duration in the critical path of the logic circuit 22 allows to always guarantee proper behavior of the logic circuit.

Thus, embodiments of the present invention have the advantage that any voltage drop increasing the length of the critical path in a certain clock also reduces the frequency of the clock signal and/or increases its period duration exactly for this clock, and the integrated logic circuit may thus continue to operate stably.

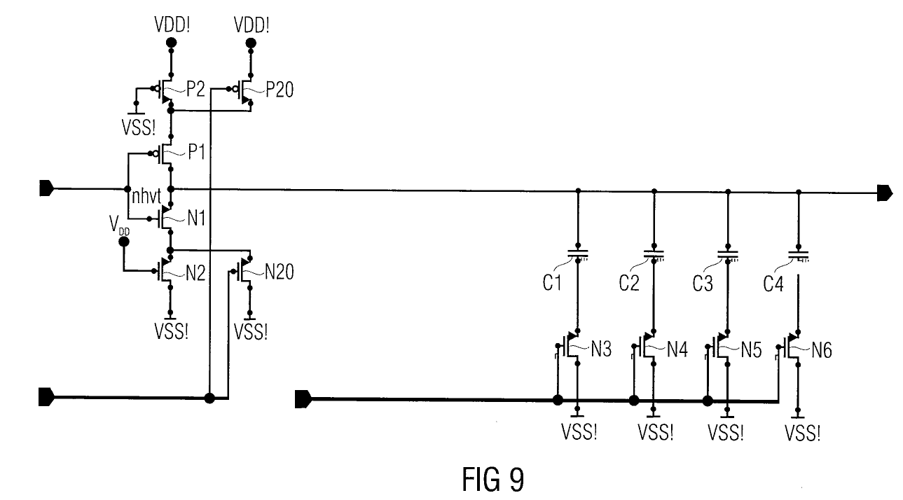

Summarizing, it is to be noted that the present invention is not limited to the respective members of the device or the discussed process, because these members and methods may vary. Accordingly, instead of inverters implemented by means of field-effect transistors, inverters with bipolar transistors are also conceivable. An oscillator element representing a combination of the oscillator elements 30-1 and 30-2 described here is shown in FIG. 9 and is equally included in the inventive concept. The terms used here are only intended to describe particular embodiments and are not used in a limiting way. Whenever the singular form or indefinite articles are used in the description and in the claims, they also refer to the plurality of these elements, as long as the overall context does not clearly indicate otherwise. The same applies the other way round.

While this invention has been described in terms of several preferred embodiments, there are alterations, permutations, and equivalents which fall within the scope of this invention. It should also be noted that there are many alternative ways of implementing the methods and compositions of the present invention. It is therefore intended that the following appended claims be interpreted as including all such alterations, permutations, and equivalents as fall within the true spirit and scope of the present invention.

What is claimed is:

1. An integrated circuit, comprising:
a logic circuit comprising logic elements in a signal path having a signal propagation duration, wherein the logic elements have switching times depending on a supply voltage, and comprising an input for a clock signal; and
an oscillator circuit comprising oscillator elements having switching times depending on the supply voltage, so that a frequency of the clock signal is adapted depending on the supply voltage to allow signal propagation of a signal through the signal path during a clock cycle of the clock signal in a case of a supply voltage drop, and comprising an output for the clock signal connected to the input of the logic circuit.

2. The integrated circuit of claim 1, wherein the signal path is a critical signal path comprising a longest signal propagation duration of the logic circuit.

3. The integrated circuit of claim 1, wherein the oscillator elements are adapted to provide an extension of the clock cycle of the clock signal in the case of a supply voltage drop, which differs less than 20% from an extension of the signal propagation through the signal path caused by the supply voltage drop.

4. The integrated circuit of claim 1, wherein the oscillator elements are adapted to provide an extension of the clock cycle of the clock signal in the case of a supply voltage drop, which differs less than 10% from an extension of the signal propagation through the signal path caused by the supply voltage drop.

5. The integrated circuit of claim 1, wherein the oscillator elements are adapted to provide an extension of the clock cycle of the clock signal in the case of a supply voltage drop, which differs less than 5% from an extension of the signal propagation through the signal path caused by the supply voltage drop.

6. The integrated circuit of claim 1, wherein the oscillator elements are adapted to reduce the frequency of the clock signal in a case of a decreasing supply voltage and to increase the frequency in the case of an increasing supply voltage.

7. The integrated circuit of claim 1, wherein the oscillator elements comprise inverters.

8. The integrated circuit of claim 1, wherein at least one of the oscillator elements comprises a transistor and an additional transistor connectable in parallel to the transistor to increase a switching speed of the oscillator element and the clock frequency of the clock signal.

9. The integrated circuit of claim 1, wherein the oscillator elements at least partially comprise transistors, which each have a channel length larger than the channel length of transistors of the integrated logic circuit.

10. The integrated circuit of claim 1, further comprising one or more capacitances selectively connectable between an output of an oscillator element and a reference potential to slow down a switching speed of the oscillator element and the clock frequency of the clock signal.

11. The integrated circuit of claim 10, further comprising several capacitances selectively connectable between the output of the oscillator element and having different capacitance values.

12. The integrated circuit of claim 10, wherein the capacitance or the capacitances comprise capacitance values in a range from 5 to 60 fF.

13. An integrated circuit comprising:
a logic circuit comprising logic elements in a critical signal path, which is a path in the logic circuit having the longest signal propagation duration, wherein the logic elements have switching times depending on a supply voltage, and comprising an input for a clock signal; and
an oscillator circuit comprising a ring oscillator structure with inverters connected in series, having switching times depending on the supply voltage, so that a frequency of the clock signal is decreased in a case of a decreasing supply voltage and is increased in a case of an increasing supply voltage to allow signal propagation of a signal through the critical signal path during a clock cycle of the clock signal in a case of a supply voltage drop, and comprising an output for the clock signal connected to the input of the logic circuit.

14. The integrated circuit of claim 13, wherein at least one of the inverters comprises a transistor and an additional transistor connectable in parallel to the transistor to increase a switching speed of the inverter and the clock frequency of the clock signal.

15. The integrated circuit of claim 13, wherein the inverters at least partially comprise transistors that each have a channel length larger than a channel length of transistors of the integrated logic circuit.

16. The integrated circuit of claim 13, further comprising one or more capacitances selectively connectable between an output of an inverter and a reference potential to slow down a switching speed of the inverter and the clock frequency of the oscillator.

17. The integrated circuit of claim 16, wherein the capacitance or the capacitances comprise capacitance values in a range from 5 to 60 fF.

18. A device on a chip with an unstabilized voltage supply, wherein the chip comprises an integrated logic circuit comprising logic elements in a signal path that has a signal propagation duration, wherein the logic elements have switching times depending on a supply voltage, comprising:
a unit for generating a clock signal for the integrated logic circuit depending on the supply voltage, so that a frequency of the clock signal is adapted depending on the supply voltage to allow signal propagation of a signal through the signal path during a clock cycle of the clock signal in a case of a supply voltage drop.

19. The device of claim 18, wherein the unit for generating is adapted to reduce the frequency of the clock signal in a case of a decreasing supply voltage and to increase the frequency in the case of an increasing supply voltage.

20. The device of claim 18, wherein the signal path is a critical signal path comprising a longest signal propagation duration of the logic circuit.

21. A method for clock generation on a chip with an unstabilized voltage supply, wherein the chip comprises an integrated logic circuit comprising logic elements in a signal path having a signal propagation duration, wherein the logic elements have switching times depending on a supply voltage, comprising:
generating a clock signal for the integrated logic circuit depending on the supply voltage, so that a frequency of the clock signal is adapted depending on the supply voltage to allow signal propagation of a signal through the signal path during a clock cycle in a case of a supply voltage drop.

22. The method of claim 21, wherein the frequency of the clock signal is reduced in a case of a decreasing supply voltage and is increased in a case of an increasing supply voltage.

23. The method of claim 21, further comprising setting the frequency of the clock signal to a nominal frequency for a nominal supply voltage.

24. The method of claim 23, wherein setting the frequency comprises connecting a certain number of oscillator elements to an oscillator generating the clock signal.

25. The method of claim 23, wherein setting the frequency comprises connecting one or more capacitances between an output of one or more oscillator elements of an oscillator generating the clock signal to reduce the frequency of the clock signal.

26. The method of claim 23, wherein setting the frequency comprises connecting one or more transistors in parallel to one or more transistors of one or more oscillator elements of an oscillator generating the clock signal to increase the frequency of the clock signal.

27. A method for producing an integrated circuit, comprising:
generating a logic circuit in a chip having logic elements in a signal path comprising a signal propagation duration, wherein the logic elements have switching times depending on a supply voltage; and
providing an oscillator circuit in the chip comprising oscillator elements having switching times depending on the supply voltage, so that a frequency of a clock signal of the oscillator circuit depends on the supply voltage to allow signal propagation of a signal through the signal path during a clock cycle of the clock signal in a case of a supply voltage drop.

28. The method of claim 27, wherein, when generating the oscillator circuit, there are at least partially generated transistors each having a channel length larger than a channel length of transistors generated when generating the integrated logic circuit.

29. The method of claim 27, further comprising:
determining a certain number of oscillator elements of the oscillator circuit so that a frequency of the clock signal is above a nominal frequency for a nominal supply voltage;
connecting one or more capacitances between an output of one or more oscillator elements of the oscillator circuit to reduce the frequency of the clock signal below the nominal frequency; and
connecting one or more transistors in parallel to one or more transistors of one or more oscillator elements of the oscillator circuit to set the frequency of the clock signal to the nominal frequency.

30. An integrated circuit, comprising:
a logic circuit comprising logic elements in a signal path having a signal propagation duration, wherein the logic elements have switching times depending on a supply voltage, and comprising an input for a clock signal; and
an oscillator means, which comprises oscillator elements having switching times depending on the supply voltage and an output for the clock signal connected to the input of the logic circuit, for adapting a frequency of the clock signal depending on the supply voltage to allow signal propagation of a signal through the signal path during a clock cycle of the clock signal in a case of a supply voltage drop.
